(19) United States
(12) Patent Application Publication
(10) Pub. No.: US 2023/0194624 A1
(43) Pub. Date: Jun. 22, 2023

(54) BATTERY MANAGEMENT SYSTEM FOR CLASSIFYING A BATTERY MODULE

(71) Applicant: LISA DRÄXLMAIER GMBH, Vilsbiburg (DE)

(72) Inventors: Florian HINTERBRANDNER, Schönau am Königssee (DE); Simon MEIER, München (DE); Paul OBERMAYER, München (DE)

(73) Assignee: LISA DRÄXLMAIER GMBH, Vilsbiburg (DE)

(21) Appl. No.: 18/108,887

(22) Filed: Feb. 13, 2023

Related U.S. Application Data
(63) Continuation of application No. PCT/EP2021/069620, filed on Jul. 14, 2021.

(30) Foreign Application Priority Data
Aug. 11, 2020 (DE) 102020121098.1

(51) Int. Cl. G01R 31/396; G01R 31/3835; G01R 31/367

(52) U.S. Cl. CPC G01R 31/396; G01R 31/3835; G01R 31/367

(57) ABSTRACT

A battery management system for classifying a battery module includes an interface and a processor. The battery module has a first and a second battery cell. The processor is configured to determine reference voltage curve on the basis of a mean voltage value of a first voltage curve associated with the first battery cell and a second voltage curve associated with a second battery cell and compare the first voltage curve to the reference voltage curve in order to obtain a first metric, and compare the second voltage curve to the reference voltage curve in order to obtain a second metric, and assign to the first voltage curve a first electrical characteristic and to the second voltage curve section of the reference voltage curve a second electrical characteristic in order to classify the battery module based on the first electrical characteristic and the second electrical characteristic.

### CROSS-REFERENCE TO RELATED APPLICATIONS

This application is a continuation of International Application No. PCT/EP2021/069620, filed on Jul. 14, 2021, which claims priority to and the benefit of German Application No. 102020121098.1 filed on Aug. 11, 2020. The disclosures of the above applications are incorporated herein by reference.

### FIELD

The present disclosure relates to a battery management system and a method for classifying a battery module with battery cells.

### BACKGROUND

The statements in this section merely provide background information related to the present disclosure and may not constitute prior art.

Battery modules, whose voltage curve is outside the typical normal distribution for the cell type and aging condition during a loading phase, can currently only be visually identified by specialized personnel. This is connected with considerable time expenditure and error potential due to the manual as well as monotonous work.

The determination of the achieved product quality is indispensable to improve the manufacturing process of battery systems. Fully automatic measurement data is collected in digital form for this purpose in modern manufacturing plants. The use of Machine Learning Methods, are cost effective and provide quick full inspection, is available for the assessment of this data. The machine learning model—in contrast to a human being—additionally displays no signs of fatigue due to the monotonous work.

### SUMMARY

This section provides a general summary of the disclosure and is not a comprehensive disclosure of its full scope or all of its features.

In one form, the present disclosure includes a battery management system and a method for classifying battery modules that detect anomalies in the battery modules and classifies the anomalies in a number of ways. It is especially demonstrated that machine learning methods are suitable for detecting anomalies in battery systems.

In one form, the present disclosure is based on the idea that the anomalies can be discovered with the aid of voltage curves of the battery modules. The effects of defective internal resistance values, capacity values, and offset voltages can thus be deduced with the aid of the electrical connections of a battery model. It was determined that all observed effects can be described with the aid of the three mentioned physical variables. Different anomaly types as well as a normal case can be defined based on this realization.

According to a first aspect, the present disclosure provides a battery management system for classifying a battery module. The battery module has a first battery cell and a second battery cell. The battery management system comprises an interface and a processor. The interface is configured to obtain a first voltage curve over the first battery cell and a second voltage curve over the second battery cell, wherein the first voltage curve has a first voltage curve section and a second voltage curve section, and wherein the second voltage curve has a third voltage curve section and a fourth voltage curve section.

The processor is configured to: determine a reference voltage curve based on a mean voltage value from the first voltage curve and the second voltage curve, wherein the reference voltage curve has a first reference voltage curve section and a second reference voltage curve section; compare the first voltage curve to the reference voltage curve in order to obtain a first metric which specifies a first voltage deviation between the first voltage curve section and the first reference voltage curve section and a second voltage deviation between the second voltage curve section and the second reference voltage curve section; compare the second voltage curve to the reference voltage curve in order to obtain a second metric which indicates a third voltage deviation between the third voltage curve section and the first reference voltage curve section and the first reference voltage curve section and a fourth voltage deviation between the fourth voltage curve section and the second reference voltage curve section; assign a first electrical characteristic to the first voltage curve section and a second electrical characteristic to the second voltage curve section if the first metric is greater than the second metric in order to classify the battery module by means of the first electrical characteristic and the second electrical characteristic; or assign a third electrical characteristic to the third voltage curve section and assign a fourth electrical characteristic to the fourth voltage curve section if the first metric is smaller than the second metric in order to classify the battery module by means of the third electrical characteristic and the fourth electrical characteristic.

The technical advantage is thereby attained as a result of anomalies in the battery modules can be detected, whereby a differentiation between flawless battery modules (that is, normal cases) and defective battery modules is made possible.

According to one form of the battery management system, the battery management system comprises a memory, which is configured to store a multitude of electrical characteristics, wherein the processor is configured to read out the respective electrical characteristics from the memory.

The electrical characteristics can be stored and read out in this way.

According to one form of the battery management system, the processor is configured to determine the reference voltage curve on the basis of the first voltage curve and the second voltage curve.

In this way, the technical advantage is achieved that a reference voltage curve for a battery module is efficiently calculated.

According to one form of the battery management system, the reference voltage curve comprises a median or average of the first voltage curve and the second voltage curve.

In this way, the technical advantage is achieved that a reference voltage curve for a battery module is efficiently calculated.

According to one form of the battery management system, the battery module has a third battery cell, and the interface is configured to obtain a third voltage curve over the third battery cell, wherein the processor is configured to determine the reference voltage curve on the basis of the first voltage curve, the second voltage curve, and the third voltage curve.

According to one form of the battery management system, the reference voltage curve comprises a median, an average, or a mode of the first voltage curve, the second voltage curve, and the third voltage curve.

In this way, the technical advantage is achieved that a reference voltage curve for a battery module is produced, which serves for detecting the battery cell which differs most with regard to the voltage curve from the other battery cells of the battery module.

According to one form of the battery management system, the processor is configured to: determine the first electrical characteristic on the basis of the first voltage curve section of the first voltage curve and the second electrical characteristic on the basis of the second voltage curve section of the first voltage curve by means of a principal component analysis, wherein the first electrical characteristic represents the first voltage curve section and the second electrical characteristic represents the second voltage curve section; and/or determine the third electrical characteristic on the basis of the third voltage curve section of the second voltage curve and the fourth electrical characteristic on the basis of the fourth voltage curve section of the second voltage curve by means of the principal component analysis, wherein the third electrical characteristic represents the third voltage curve section of the second voltage curve and the fourth electrical characteristic represents the fourth voltage curve section of the second voltage curve.

The electrical characteristics can be efficiently determined in this way.

According to one form of the battery management system, the processor is configured to determine a first electrical feature on the basis of the first voltage curve section of the first voltage curve, a second electrical feature on the basis of the second voltage curve section of the first voltage curve, a third electrical feature on the basis of the third voltage curve section of the second voltage curve, and a fourth electrical feature on the basis of the fourth voltage curve section of the second voltage curve.

According to one form of the battery management system, the first electrical feature corresponds to an offset voltage of the first battery cell and the third electrical feature corresponds to a further offset voltage of the second battery cell, wherein the second electrical feature corresponds to an internal resistance of the first battery cell and the fourth electrical feature corresponds to a further internal resistance of the second battery cell.

In this way, the technical advantage is achieved that the electrical features of battery cells of a battery module can be efficiently extracted, whereby an anomaly occurring in the battery module can be described with the aid of the offset voltage and the internal resistance of a corresponding battery cell.

According to one form of the battery management system, the processor is configured to classify the battery module by means of a classification algorithm, wherein the classification algorithm comprises at least one of the following: a logistic regression, support vector machine, random forest, multilayer perceptron, and one-class support vector machine.

In this way, the technical advantage is achieved that a battery module is efficiently classified in order to determine if the battery module is flawless or defective.

According to one form of the battery management system, the interface is configured to obtain a first multitude of voltage curves and a second multitude of voltage curves, wherein each of the first multitude of voltage curves of a battery cell corresponds to a multitude of battery modules and each of the second multitude of voltage curves of a second battery cell corresponds to a multitude of battery modules, wherein the interface is configured to manage the multitude of battery modules as flawless, wherein the processor is configured to classify each battery module of the multitude of battery modules by means of a further classification algorithm in order to generate a reference group on the basis of the classification.

In this way, the technical advantage is achieved that a reference group of flawless battery modules is efficiently formed and a strict boundary for flawless battery modules is defined within the feature space, whereby the battery modules located outside of this boundary can be declared as anomalies.

According to another form of the battery management system, the processor is configured to classify the multitude of battery modules by means of a further classification algorithm, wherein the further classification algorithm comprises at least one of the following: a logistic regression, support vector machine, random forest, multilayer perceptron, and one-class support vector machine.

In this way, the technical advantage is achieved that a reference group of flawless battery modules is efficiently formed and a strict boundary for flawless battery modules is defined within the feature space.

According to one form of the battery management system, the first voltage curve has a fifth voltage curve section, and the second voltage curve has a sixth voltage curve section, wherein the processor is configured to extract a fifth feature on the basis of the fifth voltage curve section of the first voltage curve and a sixth feature on the basis of the sixth voltage curve section of the second voltage curve.

According to one form of the battery management system, the fifth feature corresponds to a capacity of the first battery cell and the sixth feature corresponds a further capacity of the second battery cell.

In this way, the technical advantage is achieved that the electrical features of battery cells of a battery module are efficiently extracted, whereby an anomaly occurring in the battery module can be described with the aid of the offset voltage, the cell capacity, and/or the internal resistance of a corresponding battery cell.

According to one form of the battery management system, the interface is configured to obtain a number of groups to be generated, a further first multitude of voltage curves, and a further second multitude of voltage curves, wherein each of the further first multitude of voltage curves of a first battery cell corresponds to a further multitude of battery modules and each of the further second multitude of voltage curves corresponds to a second battery cell of one of the further multitude of battery modules, wherein the processor is configured to assign each battery module of the further multitude of battery modules by means of the classification algorithm to a multitude of groups, wherein the quantity of the multitude of groups is equal to the number of groups to be generated.

In this way, the technical advantage is achieved that the battery modules are efficiently classified, whereby the anomalies in the battery modules are detected and the anomalies are classified in different ways.

According to a second aspect, the present disclosure provides a means of a method for battery management. The method includes the following process steps: obtaining a first voltage curve over the first battery cell of a battery module and a second voltage curve over a second battery cell of the battery module, wherein the first voltage curve has a first voltage curve section and a second voltage curve section, and the second voltage curve has a third voltage curve section and a fourth voltage curve section; determining a reference voltage curve on the basis of mean voltage values of the first voltage curve and the second voltage curve, wherein the reference voltage curve has a first reference voltage curve section and a second reference voltage curve section; comparing the first voltage curve to the reference voltage curve in order to obtain a first metric, which indicates a first voltage deviation between the first voltage curve section and the first reference voltage curve section and a second voltage deviation between the second voltage curve section and the second reference voltage curve section; comparing the second voltage curve to the reference voltage curve in order to obtain a second metric, which indicates a third voltage deviation between the third voltage curve section and the first reference voltage curve section and a fourth voltage deviation between the fourth voltage curve section and the second reference voltage curve section; assigning a first electrical characteristic to the first voltage curve section and a second electrical characteristic to the second voltage curve section if the first metric is greater than the second metric in order to classify the battery module by means of the first electrical characteristic and the second electrical characteristic; or assigning a third electrical characteristic to the third voltage curve section and a fourth electrical characteristic to the fourth voltage curve section if the first metric is smaller than the second metric in order to classify the battery module by means of the third electrical characteristic and the fourth electrical characteristic.

In this way, the technical advantage is achieved that anomalies in the battery modules are detected, whereby a differentiation between flawless battery modules (that is, normal cases) and defective battery modules is made possible.

All of the forms listed with reference to the battery management system according to the first aspect also apply as forms for the method according to the second aspect.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 shows a schematic representation of a battery management system, according to the present disclosure for classifying a battery module;

FIG. 2 shows a table of the defined anomaly types, according to the present disclosure;

FIG. 3 shows an example for advantageously and disadvantageously selected parameter settings, according to the present disclosure;

FIG. 4 shows an example of a voltage curve and interpolation of the signal, according to the present disclosure;

FIG. 5 shows an example of a signal with an atypical signal path, according to the present disclosure;

FIG. 6 shows a signal decomposed by discrete wavelet transformation (DWT) from the example of FIG. 5 and the qualitative progression of a section-wise linear cost function, according to the present disclosure;

FIG. 7 shows an example of the segmentation of a voltage curve, according to the present disclosure;

FIG. 8 shows simulated voltage curves of a battery module with a defective battery cell in one form, according to the present disclosure;

FIG. 9 shows an example of the feature vectors generated from a training data set, according to the present disclosure;

FIG. 10 shows a table of the results of the diverse classification algorithms during training in one form, according to the present disclosure;

FIG. 11 shows a flow diagram of a method according to one form, according to the present disclosure; and

FIG. 12 is a flow diagram for a method according to one form of the present disclosure.

The drawings described herein are for illustration purposes only and are not intended to limit the scope of the present disclosure in any way.

### DETAILED DESCRIPTION

Reference is made in the following detailed description to the enclosed figures, which represent a part thereof and in which are shown depictions of specific forms, in which the present disclosure can be implemented. It is understood that other forms can be used, and structural or logical modifications can be undertaken without deviating from the concept of the present disclosure. The following detailed description is therefore not to be understood in a limiting sense. It is also understood that the features of the diverse forms and variations described herein can be combined with one another, provided nothing else is otherwise specified.

The aspects and forms of the present disclosure are described with reference to the figures wherein identical reference characters generally refer to the same elements. Numerous specific data are presented in the following description for explanatory purposes in order to convey an in depth understanding of one or several aspects of the present disclosure.

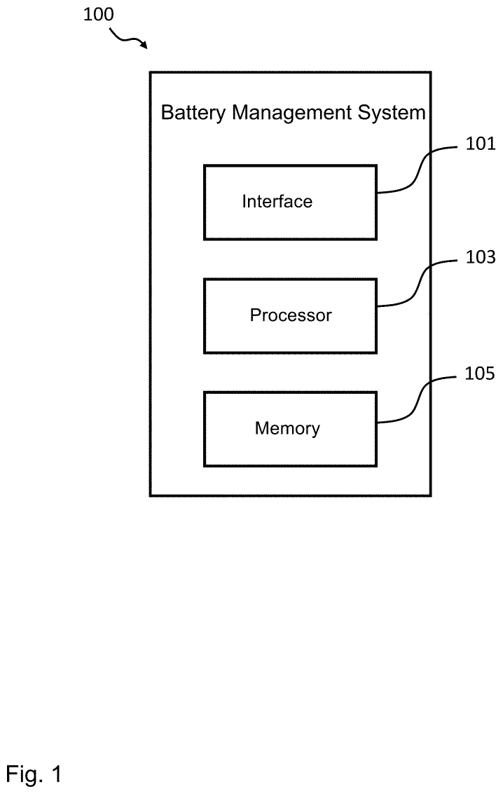

FIG. 1 shows a schematic representation of a battery management system 100 for classifying a battery module according to one form, wherein the battery module has at least a first battery cell and a second battery cell. As depicted in FIG. 1, the battery management system 100 comprises an interface 101, a processor 103, and a memory 105, whose functions are considered in more detail in the following.

In one form, the interface 101 is configured to obtain a first voltage curve over the first battery cell and a second voltage curve over the second battery cell, wherein the first voltage curve has a first voltage curve section and a second voltage curve section, and the second voltage curve has a third voltage curve section and a fourth voltage curve section.

In one form, the processor 103 is configured to determine a reference voltage curve on the basis of a mean voltage value of the first voltage curve and the second voltage curve, wherein the reference voltage curve has a first reference voltage curve section and a second reference voltage curve section. In one form, the processor 103 is configured to determine the reference voltage curve on the basis of the first voltage curve and the second voltage curve and the reference voltage curve comprises a median or an average of the first voltage curve and the second voltage curve.

The processor 103 is further configured to compare the first voltage curve to the reference voltage curve in order to obtain a first metric which indicates a first voltage deviation between the first voltage curve section and the first reference voltage curve section and a second voltage deviation between the second voltage curve section and the second reference voltage curve section; and compare the second voltage curve to the reference voltage curve in order to obtain a second metric which indicates a third voltage deviation between the third voltage curve section and the first reference voltage curve section and a fourth voltage deviation between the fourth voltage curve section and the second reference voltage curve section.

If the first metric is greater than the second metric, the processor 103 is configured to assign a first electrical characteristic to the first voltage curve section and a second electrical characteristic to the second voltage curve section in order to classify the battery module by means of the first electrical characteristic and the second electrical characteristic.

In one form, the processor 103 is configured to determine the first electrical characteristic on the basis of the first voltage curve section of the first voltage curve and the second electrical characteristic on the basis of the second voltage curve section of the first voltage curve by means of a principal component analysis, wherein the first electrical characteristic represents the first voltage curve section of the first voltage curve and the second electrical characteristic represents the second voltage curve section of the first voltage curve.

As an alternative, the processor 103 can be configured to assign a third electrical characteristic to the third voltage curve section and assign a fourth electrical characteristic to the fourth voltage curve section if the first metric is smaller than the second metric in order to classify the battery module by means of the third electrical characteristic and the fourth electrical characteristic.

In one form, the processor 103 is configured to determine the third electrical characteristic on the basis of the third voltage curve section of the second voltage curve and the fourth electrical characteristic on the basis of the fourth voltage curve section of the second voltage curve by means of the principal component analysis, wherein the third electrical characteristic represents the third voltage curve section of the second voltage curve and the fourth electrical characteristic represents the fourth voltage curve section of the second voltage curve.

In one form, the memory 105 is configured to store a multitude of electrical characteristics, wherein the processor 103 is configured to read out the respective electrical characteristic from the memory.

With regard to the classification, the processor 103 is configured to classify the battery module by means of a classification algorithm, wherein the classification algorithm comprises at least one of the following: a logistic regression, support vector machine, random forest, multilayer perceptron, and one-class support vector machine.

In one form, the battery module further has a third battery cell and the interface 101 is configured to obtain a third voltage curve over the third battery cell, wherein the processor 103 is configured to determine the reference voltage curve on the basis of the first voltage curve, the second voltage curve, and the third voltage curve. In this case, the reference voltage curve comprises a median, an average, or a mode of the first voltage curve, the second voltage curve, and the third voltage curve.

In one form, the processor is configured to determine a first electrical feature on the basis of the first voltage curve section of the first voltage curve, a second electrical feature on the basis of the second voltage curve section of the first voltage curve, a third electrical feature on the basis of the third voltage curve section of the second voltage curve, and a fourth electrical feature on the basis of the fourth voltage curve section of the second voltage curve, wherein the first electrical feature corresponds to an offset voltage of the first battery cell and the third electrical feature corresponds to another further offset voltage of the second battery cell, wherein the second electrical feature corresponds to an internal resistance of the first battery cell and the fourth electrical feature corresponds to a further internal resistance of the second battery cell.

In one form, the interface 101 is configured to obtain a first multitude of voltage curves and a second multitude of voltage curves, wherein each of the first multitude of voltage curves of a first battery cell corresponds to a multitude of battery modules and each of the second multitude of voltage curves of a second battery cell corresponds to a multitude of battery modules, wherein the interfaces are configured to manage the multitude of battery modules as flawless.

In this case, the processor 103 is configured to classify each battery module of the multitude of battery modules by means of a further classification algorithm in order to form a reference group on the basis of the classification, wherein the further classification algorithm comprises at least one of the following: a logistic regression, support vector machine, random forest, multilayer perceptron, and one-class support vector machine.

In one form, the first voltage curve has a fifth voltage curve section, and the second voltage curve has a sixth voltage curve section, wherein the processor 103 is configured to extract a fifth feature on the basis of the fifth voltage curve section of the first voltage curve and a sixth feature on the basis of the sixth voltage curve section of the second voltage curve. The fifth feature corresponds to a capacity of the first battery cell and the sixth feature corresponds to a further capacity of the second battery cell.

In one form, the interface 101 is further configured to obtain a number of groups to be generated, a further first multitude of voltage curves, and a further second multitude of voltage curves, wherein each of the further first multitude of voltage curves of a first battery cell corresponds to a further multitude of battery modules and wherein each of the further second multitude of voltage curves of a second battery cell corresponds to one of the further multitude of battery modules. Accordingly, the processor 103 is configured to assign each battery module of the further multitude of battery modules by means of the classification algorithm to a multitude of groups, wherein the quantity of the multitude of groups is equal to the number of groups to be generated.

Fully automated battery modules can be analyzed with regard to their behavior, and possible anomalies can be detected and categorized by means of the forms of the present disclosure.

In this way the following advantages can be achieved:
Savings in costs, since possible complaints can be reduced early on (directly after production)
Method applicable to individual battery modules
Localization of the affected module
Categorization of the anomalies (indication of causes)
100% testing of all modules

The present disclosure relates to the following aspects: battery simulation, identification of outliers and extraction of features, classification algorithms, and anomaly detection, which are considered in more detail in the following.

Real anomaly types are simulated and generated in uniform distribution with the aid of a battery simulation model. A subsequent data pre-processing extracts the features (feature vectors) needed for the subsequent categorization and recognizes foreign or thus-far unknown anomalies (outliers). A classification model assigns (categorizes) a known group to each module, wherein the decisions made by a downstream anomaly detector regarding the presence of an anomaly are again critically considered. A purely binary assignment (anomaly or normal case) takes place, however, in these cases.

The simulation of anomalies provides a method to obtain the change in physical behavior with regard to its “normal” behavior and be able to repeatedly simulate the manifestation of this changed behavior. This must take place within the bounds within which this anomaly occurs in order to be able to assign a cause to the anomaly.

Three steps, which are required in order to be able to securely generate the desired accuracy of this changed behavior, are additionally carefully considered in the following:
Simulation of the behavior of the physical system
Definition of the parameters which trigger anomalies
Generation of parameter distribution

Simulating the Behavior of the Physical System

The behavior of the real physical system must be simulated as exactly as possible by means of the simulation model with reference to the variable to be analyzed. This comes about in that the parameters of the simulation model are adapted in such a way that the deviation from the real behavior to be simulated is as minimal as possible.

This adaptation comes about by way of a combination of optimization algorithms, which are used in a defined order. These determine the parameter combination that has the least deviation of the simulation with respect to the real measurements. This parameter adaptation is thus always based on a parameter set that was initially already adapted to the general behavior. After this adaptation, it can be considered a “digital twin” which reflects the behavior of a specific real system.

Defining the Parameters which Trigger Anomalies

The parameters that trigger anomalies must be determined in order to be able to selectively generate these. This assignment can occur via pure data evaluation or via the special field that can assign causes and consequently parameters to behavior patterns. Three parameters which can characterize anomalies were defined. All possible combinations of these parameters were defined in the cases below.

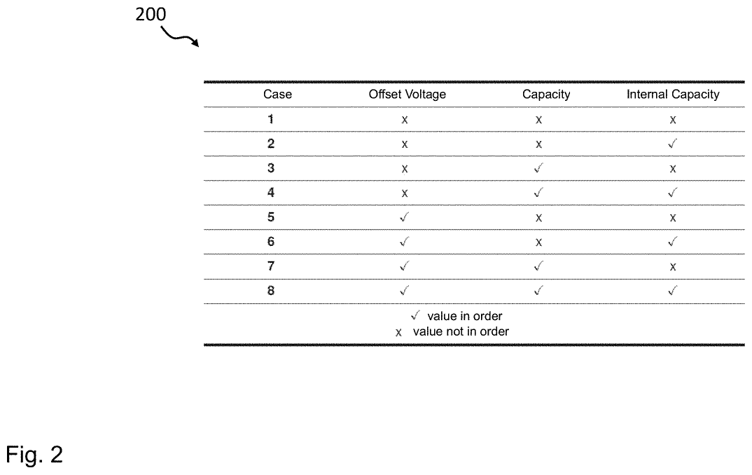

FIG. 2 shows a table 200 of the defined anomaly types in one form. As can be seen in FIG. 2, all occurring anomalies can be described with the aid of the offset voltage, the cell capacity, and the internal resistance.

Generating the Anomaly Distribution

The manifestations of the parameters that trigger anomalies can be determined through the analysis of many real anomaly cases. These manifestations of parameters serve as a scale to obtain parameter limits for specific anomalies.

These determined limits can now be used to independently generate anomalies that correspond to those of real systems in their behavior and manifestation. The generated anomaly cases can be created any number of times and in any combination and manifestation, and machine learning algorithms can be trained in doing so.

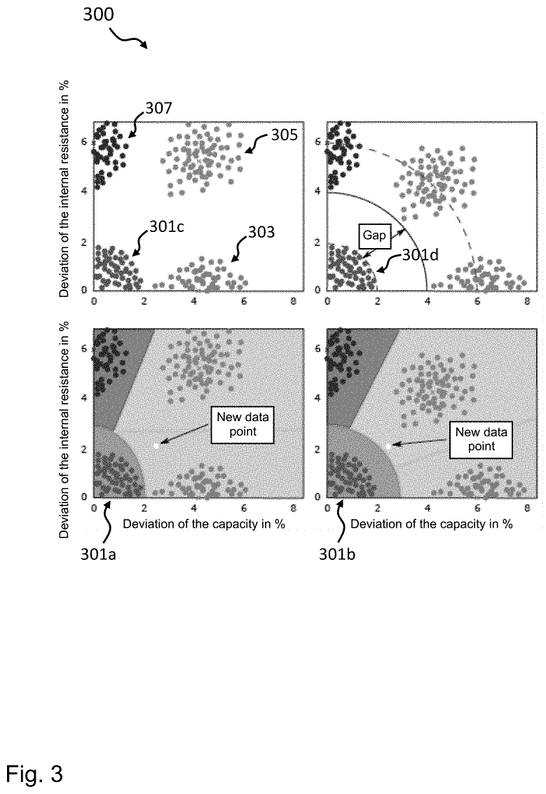

Besides numerous advantages, the generation of training data sets with the aid of a simulation model also brings with it challenges. The selection of the simulation parameters is thus desired for the subsequent application of the trained model with real data. The risk exists, for example, that the parameters may be unfavorably selected in the training data set, so that the occurrence of specific cases is favored. FIG. 3 shows an example of favorably (top right) and unfavorably (bottom left) selected parameter settings.

In FIG. 3 top left, it can be seen that there is a very small deviation between the normal case 301c and the mere capacity defect 303, whereas the two other anomaly cases 305, 307 display a greater deviation from the normal case. Below are shown exemplary decision limits, which can be defined by a classifier with the aid of training data. The classifier would assign a new data point, which displays abnormalities in the internal resistance as well as in the capacity, to the group of capacity defects, as unfavorable decision limits were defined due to the training data. This is remedied with a skillful arrangement of the parameters (see FIG. 3 top right). Since all centers of the abnormal data point are located on a circular arc, they have an identical distance to the center of the normal cases. Consequently, no case is artificially favored and a correct classification (see FIG. 3 bottom right) is possible.

It can further be seen in FIG. 3 that it is decisive to set up the distribution of the parameters in a circular pattern around the normal case 301a-d for the training of classification algorithms in this application case. The parameters and their combinations are generated in such a way that a gap is present between the cases 301a-d. This guarantees a differentiation between the individual anomalies. Two parameters are presented here as an example within a two-dimensional space. This correlation must, however, also be adhered to for higher dimensional ratios. The circular arrangement around the normal case thereby provides that the generated anomalies are uniformly assessed in their weighting; normal cases and anomalies are likewise generated in equal numbers.

A laborious data pre-processing is completed before machine learning methods can be used to detect and classify anomalies. It is performed via several process steps which are listed in the following.

Filtering the Time Series

In one form, the batteries to be assessed consist of either 28 or 33 modules. Independently from the battery type, however, data is recorded for 33 modules. If the battery has only 28, then default values are used for the remaining five. The removal of these modules with their default values from the real data set constitutes the first step of the data pre-processing. The individual cell voltages are read out in order to be able to identify the affected modules. If a module only possesses default values as cell voltages and the module number is greater than 28, then this module, with the corresponding time series, is deleted.

Determining the Trigger Point

In addition to different lengths of the time series, the real data can also contain time-shifted signals. The time shift is compensated by means of a key edge triggering of the signal. The first derivative of the signal and a previously defined trigger limit serve for dynamically detecting this edge. If the value of the slope is greater than this trigger limit, then this is the desired edge.

Interpolating the Time Series

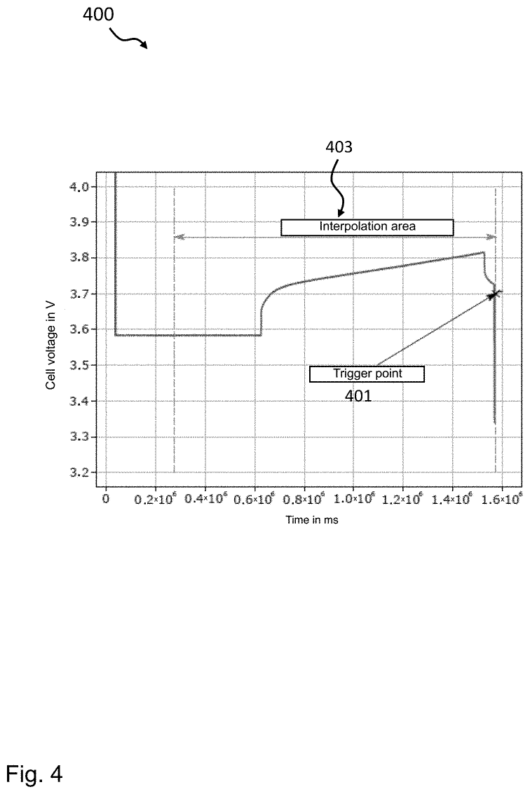

The real data used has different increments within a time series. A distortion of the signal characteristic would occur if the signal were to be considered without the corresponding time values. For further processing, however, the voltage values should be considered exclusively without time information. An interpolation of the signal is desired to make this possible. This work step is represented in FIG. 4. The end of the interpolation range 403 is determined with the trigger point 401 defined above. The start point is calculated from the difference between the end point and a previously specified time span. A linear interpolation within this range brings about a standardization of the increments. The individual signals can thus be compared to each other independently from the time reference without thereby distorting the characteristic of the signals.

As can furthermore be seen in FIG. 4, this procedure is suitable for filtering default values which can appear at the start of the recording. A time series always possesses default values when the recording of the data is active, but a measurement is not yet being carried out. If such a default value occurs within the actual signal characteristic, then it cannot be removed, since the measuring results would consequently be manipulated and information about possible defects of the measuring unit would be lost.

Smoothing the Time Series

A first-order low-pass is used to improve the ratio between the useful signal and the signal noise. However, the sampling rate is too low to allow a clear suppression of the noise without affecting the useful signal. A compromise between the remaining useful signal and the noise is met and the cutoff frequency of 0.1 Hz is empirically determined in order to still be able to define a cutoff frequency.

Filtering the Outliers

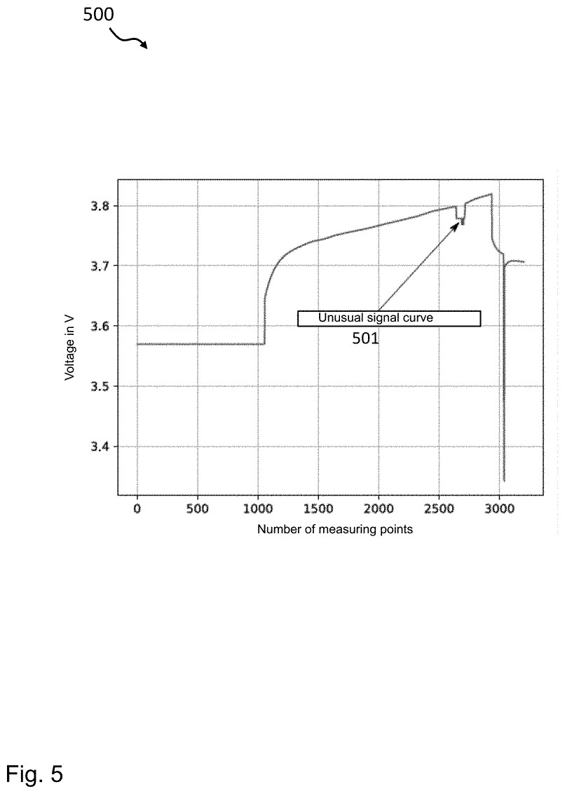

For further processing of the data, a shape similarity of the measurements that are triggered by specific features must be provided. All defined anomalies and also the normal case display this shape similarity. Voltage curves that have another characteristic must thus be previously filtered out. In FIG. 5 is represented a possible example of a signal with another atypical characteristic 501.

Dynamic time warping (DTW) can be used, for example, to detect such outliers. This method is suitable for comparing the signal curve since time shifts or distortions are compensated. Tests showed, however, that the use of DTW is connected with a significant calculation and time expenditure. This is consequently not an advantageous option in applications with limited computing power. However, to make possible the detection of such unusual characteristics, the signal is transformed by means of a discrete wavelet transformation (DWT). This causes a halving of the length of the signal without losing at the same time any significant information. The detail coefficients are subsequently considered since they contain the high frequency components of the original signal. It is determined that all generated cases in this observation differ merely in the height of four distinctive peaks. If a signal has additional peaks beside the four peaks, then this can be ascribed to deviations of the signal shape. The transformed signals can be compared to a reference signal with the aid of the Euclidian distance. However, because only the areas outside of the peaks are relevant for this comparison, a cost function ƒ_{cost} is additionally defined. The following expression was obtained for calculating the shape similarity:

$${d}_{shape} = \sqrt{{\sum }_{j = 1}^{n} {( {p}_{j} - {q}_{j} )}^{2} \cdot {f}_{cost , j}}$$

Therein, pⱼ represents the j-th detail coefficient of the signal to be examined and qⱼ represents the j-th detail coefficient of the reference signal. The squared difference of these two values is subsequently multiplied by ƒ_{cost}(i). This factor corresponds to the j-th value of the cost function. If the cost function has zero values at the locations of the peaks, then they are not considered for the determination of the shape similarity. A rectangular characteristic of the cost function is not expedient since with real data the peaks can be shifted along the x-axis. A function that increases with the distance to the peaks can be helpful. Deviations that are further spaced from the peaks are more highly weighted and deviations in the vicinity are tolerated. The higher the value of dₛₕₐₚₑ is, the more the signals differ with regard to their shape.

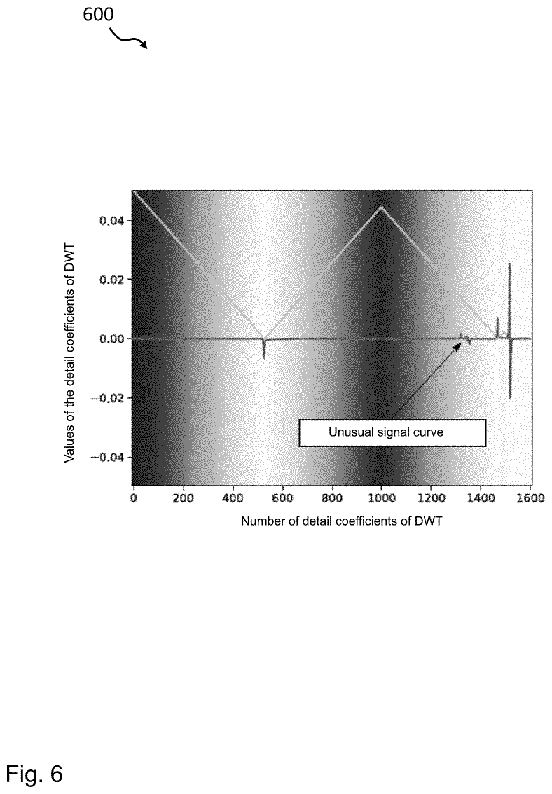

FIG. 6 shows the signal transformed by DWT from the example above and the qualitative characteristic of a section-wise linear cost function. To determine the cost function, the reference signal is initially derived in order to determine the positions of the peaks. All values of the derived signal which are smaller than a previously defined limit are set to zero. This limit is the maximum of the derivative of the signal within the range outside of the peaks. Thus, merely the derivatives of the peaks remain.

The individual values of the cost function are calculated as follows:

$${f}_{cost , j} = \{ \begin{matrix}w \cdot {d}_{peak , j}^{k} & if {q}_{j}^{′} = 0 \\ 0 & if {q}_{j}^{′} \neq 0\end{matrix}$$

The parameters w and k are defined by the programmer. The tolerance range can be varied with the aid of the weighting factor w. The exponent p determines how fast the cost function increases depending on the distance dₚₑₐₖ. At the same time, dₚₑₐₖ represents the distance to the next peak. The j-th value of the derivative of the transformed signal p is represented by pⱼ′.

Extracting the Features

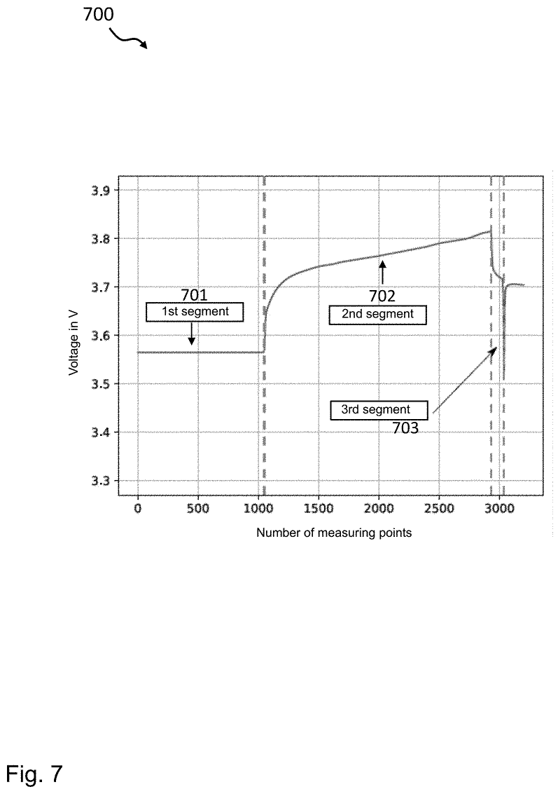

The anomalies to be examined can be described with only three physical variables—offset voltage, cell capacity, and cell internal resistance. A signal decomposition into three segments constitutes the first step of the feature extraction (see FIG. 7). Three edges are used as a result to separate the individual areas. These edges can be easily determined by means of the derivative of the signal since each signal has a similar characteristic and the measurement noise is extensively compensated.

If it is assumed that the first segment 701 is particularly suitable for determining the offset voltage, the second segment 702 serves for detecting low cell capacities, and the effect of an increased internal resistance becomes increasingly more evident in the third segment 703. It can likewise be seen from these effects that a steeper signal characteristic in the second segment 702 cannot solely be ascribed to a low cell capacity. The non-linear ratio between the cell voltage and the state of charge (SoC) can also be clearly detected during the charging process and results in a deviating dynamic behavior of the voltage curve during charging. Since the battery systems are not brought to a standardized state of charge before the end-of-line test (EoL-Test), the offset voltage can be somewhat different in each battery. All batteries that are not within the defined tolerance limits are removed following the measurement of the battery voltage at the start of the test. For this reason, it can be assumed that the majority of the cells of a battery whose voltage is within the tolerance band do not display any anomalies. The differing state of charge of the batteries does not allow the use of a rigid reference signal to differentiate between anomaly or normal case. Thus, occurring anomalies are to be declared as context-related anomalies, since the signal characteristic alone does not allow a statement about the state of the cell. In the following, the battery systems are considered on the modular plane.

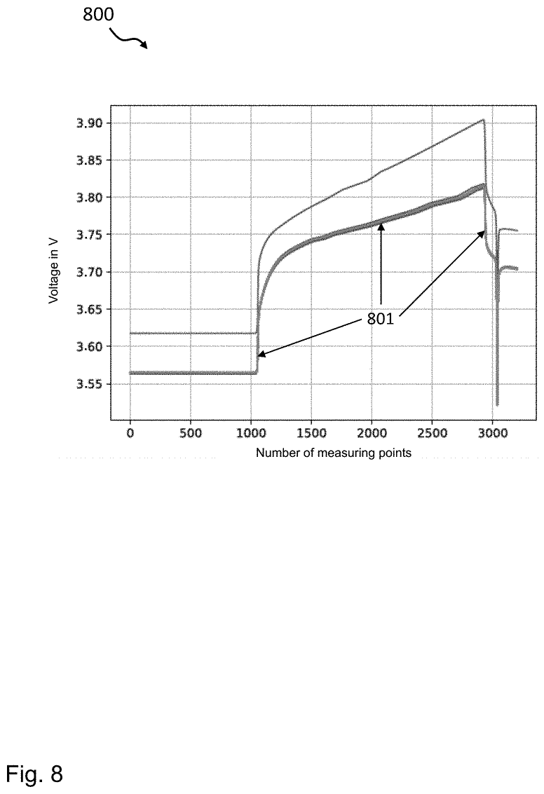

FIG. 8 shows the simulated voltage curves of a battery module with a defective battery cell in one form and the calculated reference signal 801. The voltage curve of the reference signal 801 is formed by calculating the median of all cell voltages of a module. The median is better suited as reference than the arithmetical mean value since outliers have a significantly lower influence on the median. If several voltage curves are considered, they can be represented as follows:

$$x = ( \begin{matrix}{x}_{1 , 1} & {x}_{1 , 2} & … & {x}_{1 , j} & … & {x}_{1 , n} \\ {x}_{2 , 1} & {x}_{2 , 2} & … & {x}_{2 , j} & … & {x}_{2 , n} \\ ⋮ & ⋮ & ⋱ & ⋮ & ⋱ & ⋮ \\ {x}_{i , 1} & {x}_{i , 2} & … & {x}_{i , j} & … & {x}_{i , n} \\ ⋮ & ⋮ & ⋱ & ⋮ & ⋱ & ⋮ \\ {x}_{m , 1} & {x}_{m , 2} & … & {x}_{m , j} & … & {x}_{m , n}\end{matrix} ) with i ∈ ℕ , 1 \leq i \leq m und j ∈ ℕ , 1 \leq j \leq n$$

The number of voltage curves is represented by m, and the number of measuring points is represented by n. The following applies consequently for the reference signal:

$${\vec{x}}_{ref} = ( {\tilde{x}}_{1} , {\tilde{x}}_{2} , … , {\tilde{x}}_{j} , … , {\tilde{x}}_{n} ) mit {\tilde{x}}_{j} = \{ \begin{matrix}{x}_{\frac{n + 1}{2} , j} & if n is odd \\ \frac{1}{2} ( {x}_{\frac{n}{2} , j} + {x}_{\frac{n}{2} + 1 , j} ) & if n is even\end{matrix}$$

The generated reference signal serves for detecting the cell that differs most from the other cells of a module with reference to the voltage curve. The reference signal is thereby newly formed for each module. Because it can happen that several cells of a module display different anomalies, the comparison between cell voltage and reference voltage is determined for each segment. The steps for the feature extraction in the respective segments are explained in the following.

Offset Voltage

Since an excessively high or low offset voltage represents an error, only the absolute value difference between cell and reference is of importance. The cell with the greatest difference in relation to the reference signal is accordingly the one that deviates most from the ideal.

Cell Capacity

In the second segment, it is attempted to extract information about the cell capacity. All voltages are initially set to a standardized starting value to make possible a comparison of the charging behavior. A starting value of 0 V was selected since this is easily accomplished by subtracting the first voltage value within the second segment. The cell that is most defective is subsequently also detected here. It can be recognized by the steepest voltage curve.

Internal Resistance

The offset voltage is also compensated in the third segment since only the relative voltage jump allows conclusions as to the internal resistance of a cell. Excessively high voltage jumps, which are an indication of high internal resistances, are currently likewise considered as anomalies, just as excessively low voltage jumps because an absolute value consideration of the voltage differences is also undertaken here.

To select the cell that deviates most from the reference cells with regard to its voltage curve, its segment signal [symbol] _{sec} is extracted, whereby it applies that:

$${\vec{x}}_{sec} ∈ \{ \vec{{x}_{i}} \vert {\sum }_{j = 1}^{n} {d}_{sec , i , j} = {max}_{1 \leq i \leq m} ( {\sum }_{j = 1}^{n} {d}_{sec , i , j} ) \}$$

d_{sec,i,j} is calculated as follows:

$${d}_{sec , i , j} = \{ \begin{matrix}\vert {x}_{i , j} - {\tilde{x}}_{j} \vert & for segment 1 or 3 \\ {x}_{i , j}^{′} & for segment 2\end{matrix}$$

A time series is thus obtained for each module and segment. It is now attempted to reduce the data. This is accomplished with the aid of a principal component analysis. This method is suitable here since those points that have the greatest information content are identified for each segment. Redundant information is omitted in this way. It is determined that a single point per segment is sufficient to retain the desired characteristic according to the principal component analysis. In this way, a feature vector with three inputs is obtained.

[symbol]

_{feat,k}:=(c_{k,1},c_{k,2},c_{k,3})

Input c_{k, l} with l∈ [symbol] and 1≤l≤3 of the vector [symbol] _{feat,k} represents the principal components of the l-th segment and the k-th module transformed by principal component analysis (PCA).

Since the evaluation range of the individual segments can differ greatly, an additional standardization is subsequently undertaken and a mean value of zero and an empirical variance of one are thus obtained. This step makes possible a significant increase in performance of the machine learning algorithms. If now the overall training data set is considered, one obtains the following matrix V, which consists of several feature vectors.

$$V = ( \begin{matrix}{\vec{v}}_{feat , 1} \\ {\vec{v}}_{feat , 2} \\ ⋮ \\ {\vec{v}}_{feat , N}\end{matrix} ) = ( \begin{matrix}{c}_{1 , 1} & {c}_{1 , 2} & {c}_{1 , 3} \\ {c}_{2 , 1} & {c}_{2 , 2} & {c}_{2 , 3} \\ ⋮ & ⋮ & ⋮ \\ {c}_{N , 1} & {c}_{N , 2} & {c}_{N , 3}\end{matrix} )$$

The standardization is subsequently performed by means of the following transformation:

$${\vec{z}}_{l} = \frac{{\vec{c}}_{l} - {\overline{c}}_{l} \cdot {( 1 , 1 , … , 1 )}^{T}}{{σ}_{{c}_{l}}}$$

For the standard deviation σ_{cl} applies:

$${σ}_{{c}_{l}} = \sqrt{\frac{1}{N} {\sum }_{k} {( {c}_{k , i} - {\overline{c}}_{l} )}^{2}}$$

Differences can be more clearly emphasized and different orders of magnitude of the individual features can be compensated by means of the standardization of the features.

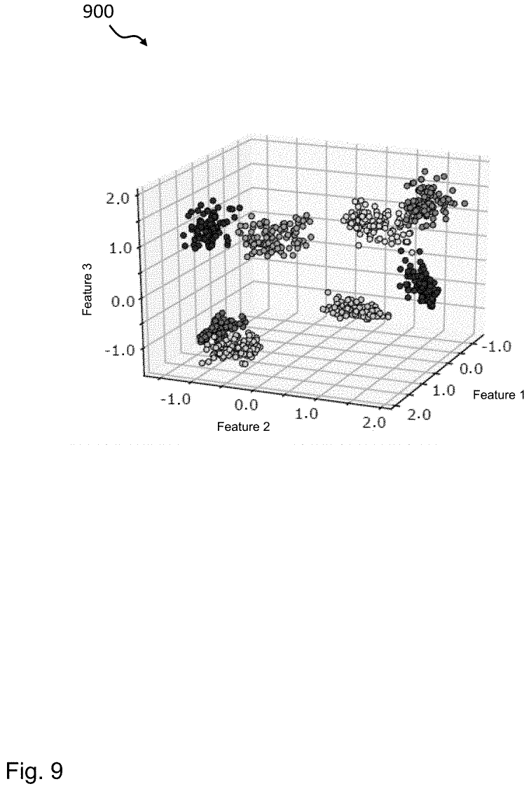

The feature vectors can be subsequently represented as points in a three-dimensional space. The data points are colored according to their groups. In FIG. 9 the individual feature vectors to the cases of Table 200 in FIG. 2 are represented. In FIG. 9 the result of the feature extraction with the aid of an exemplary data set can be seen. It can be recognized here that the various groups are clearly separated from each other. This allows one to conclude that the feature extraction has been successful.

Several classification algorithms can be tested for categorizing the anomalies, such as, for example, logistic regression, support vector machine, random forest, and multilayer perceptron.

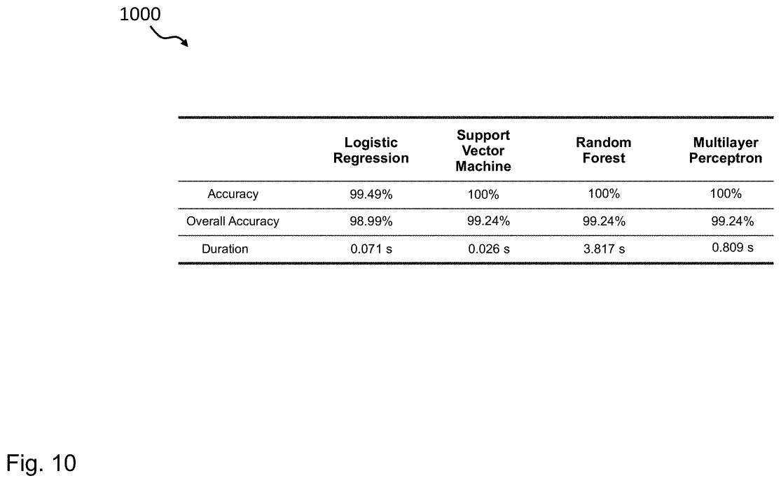

FIG. 10 shows a Table 1000 of the results of the various classification algorithms during training with k-means in one form. As can be seen in FIG. 10, the support vector machine delivers the best result, wherein the support vector machine performs a correct classification of the data within only 3% of the time required by the multilayer perceptron.

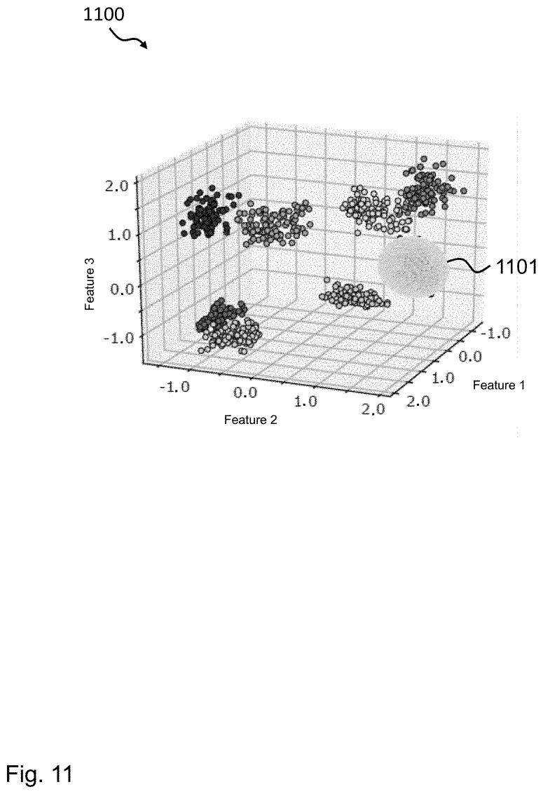

A one-class support vector machine is used after the classifier in one form in order to make possible a more restrictive consideration of an anomaly and a normal case. The latter should specify strict limits for normal cases in the feature space with the aid of normal cases, which are contained in the training data. In FIG. 11 the boundary surface 1101 generated by the one-class support vector machine can be seen. All the data points located outside of this boundary are declared as anomalies regardless of the result of the classifier. The label with the second highest probability is awarded in order to thereby make possible an assignment to an anomaly type.

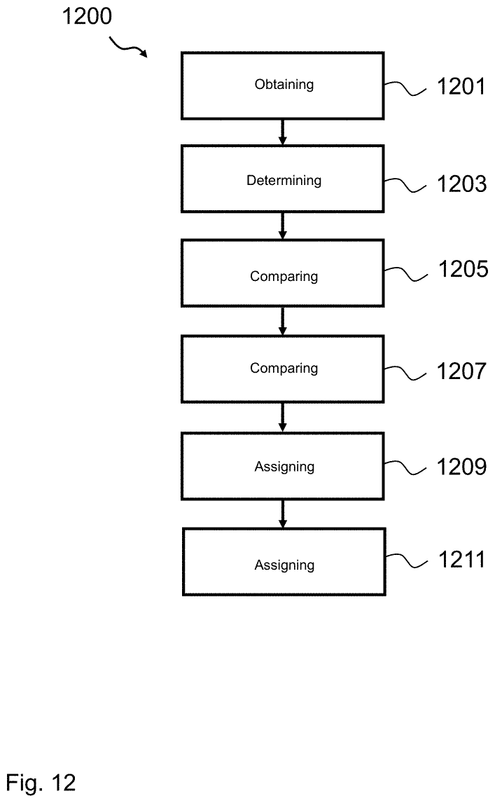

Referring now to FIG. 12, a method 1200 for battery management comprises as first method step the obtaining 1201 of a first voltage curve over a first battery cell of a battery module and a second voltage curve over a second battery cell of the battery module, wherein the first voltage curve has a first voltage curve section and a second voltage curve section, and the second voltage curve has a third voltage curve section and a fourth voltage curve section.

The method 1200 comprises as a second method step the determination 1203 of a reference voltage curve on the basis of a mean voltage value of the first voltage curve and the second voltage curve, wherein the reference voltage curve has a first reference voltage curve section and a second voltage curve section.

The method 1200 comprises as a third method step the comparison 1205 of the first voltage curve to the reference voltage curve in order to obtain a first metric, which indicates a first voltage deviation between the first voltage curve section and the first reference voltage curve section and a second voltage deviation between the second voltage curve section and the second reference voltage curve section.

The method 1200 comprises as a fourth method step the comparison 1207 of the second voltage to the reference voltage curve in order to obtain a second metric, which indicates a third voltage deviation between the third voltage curve section and the first reference voltage curve section and a fourth voltage deviation between the fourth voltage curve section and the second reference voltage curve section;

The method 1200 comprises as a fifth method step the assignment 1209 of a first electrical characteristic to the first voltage curve section and a second electrical characteristic to the second voltage curve section if the first metric is greater than the second metric in order to classify the battery module by means of the first electrical characteristic and the second electrical characteristic, or as a sixth method step the assignment 1211 of a third electrical characteristic to the third voltage curve section and a fourth electrical characteristic to the second voltage curve section if the first metric is smaller than the second metric in order to classify the battery module by means of the third electrical characteristic and the fourth electrical characteristic.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A battery management system for classifying a battery module, wherein the battery module has a first battery cell and a second battery cell, the battery management system comprising:
an interface configured to obtain a first voltage curve over the first battery cell and a second voltage curve over the second battery cell, wherein the first voltage curve has a first voltage curve section and a second voltage curve section, and wherein the second voltage curve has a third voltage curve section and a fourth voltage curve section;
a processor configured to:
determine a reference voltage curve on the basis of a mean voltage value from the first voltage curve and the second voltage curve, wherein the reference voltage curve has a first reference voltage curve section and a second reference voltage curve section;
compare the first voltage curve to the reference voltage curve in order to obtain a first metric, which indicates a first voltage deviation between the first voltage curve section and the first reference voltage curve section and a second voltage deviation between the second voltage curve section and the second reference voltage curve section;
compare the second voltage curve to the reference voltage curve in order to obtain a second metric, which indicates a third voltage deviation between the third voltage curve section and the first reference voltage curve section and a fourth voltage deviation between the fourth voltage curve section and the second reference voltage curve section;
assign to the first voltage curve section a first electrical characteristic and to the second voltage curve section a second electrical characteristic if the first metric is greater than the second metric in order to classify the battery module based on the first electrical characteristic and the second electrical characteristic; and
assign to the third voltage curve section a third electrical characteristic and to the fourth voltage curve section a fourth electrical characteristic if the first metric is smaller than the second metric in order to classify the battery module based on the third electrical characteristic and the fourth electrical characteristic.

2. The battery management system according to claim 1, further comprising a memory configured to store a multitude of electrical characteristics, wherein the processor is configured to read out a respective electrical characteristic from the memory.

3. The battery management system according claim 1, wherein the processor is configured to determine the reference voltage curve on the basis of the first voltage curve and the second voltage curve.

4. The battery management system according to claim 3, wherein the reference voltage curve comprises a median or an average of the first voltage curve and the second voltage curve.

5. The battery management system according to claim 1, wherein the battery module has a third battery cell, and the interface is configured to obtain a third voltage curve over the third battery cell, the processor is configured to determine the reference voltage curve on the basis of the first voltage curve, the second voltage curve, and the third voltage curve.

6. The battery management system according to claim 5, wherein the reference voltage curve comprises a median, an average, or a mode of the first voltage curve, the second voltage curve, and the third voltage curve.

7. The battery management system according to claim 1, wherein the processor is further configured to, at least one of the following:
determine the first electrical characteristic on the basis of the first voltage curve section of the first voltage curve and the second electrical characteristic on the basis of the second voltage curve section of the first voltage curve based on a principal component analysis, wherein the first electrical characteristic represents the first voltage curve section of the first voltage curve and the second electrical characteristic of the second voltage curve section; and
determine the third electrical characteristic on the basis of the third voltage curve section of the second voltage curve and the fourth electrical characteristic on the basis of the fourth voltage curve section of the second voltage curve based on the principal component analysis, wherein the third electrical characteristic represents the third voltage curve section of the second voltage curve and the fourth electrical characteristic represents the fourth voltage curve section of the second voltage curve.

8. The battery management system according claim 1, wherein the processor is configured to determine a first electrical feature on the basis of the first voltage curve section of the first voltage curve, a second electrical feature on the basis of the second voltage curve section of the first voltage curve, a third electrical feature on the basis of the third voltage curve section of the second voltage curve, a fourth electrical feature on the basis of the fourth voltage curve section of the second voltage curve.

9. The battery management system according to claim 8, wherein the first electrical feature corresponds to an offset voltage of the first battery cell and the third electrical feature corresponds to a further offset voltage of the second battery cell, wherein the second electrical feature corresponds to an internal resistance of the first battery cell and the fourth electrical feature corresponds to a further internal resistance of the second battery cell.

10. The battery management system according to claim 1, wherein the processor is configured to classify the battery module based on a classification algorithm, wherein the classification algorithm comprises at least one of the following: a logistic regression, support vector machine, random forest, multilayer perceptron, and one-class support vector machine.

11. The battery management system according to claim 1, wherein:
the interface is further configured to obtain a first multitude of voltage curves and a second multitude of voltage curves, wherein each of the first multitude of voltage curves of a first battery cell corresponds to one of a multitude of battery modules and each of the second multitude of voltage curves of a second battery cell corresponds to one of a multitude of battery modules, and manage as flawless the multitude of battery modules; and
the processor is further configured to classify each battery module of the multitude of battery modules in order to form a reference group on the basis of the classification.

12. The battery management system according to claim 11, wherein:
the processor is configured to classify the multitude of battery modules based on a further classification algorithm, and
the further classification algorithm comprises at least one of the following: a logistical regression support vector machine, random forest, multilayer perceptron, and one-class support vector machine.

13. The battery management system according to claim 1, wherein the first voltage curve has a fifth voltage curve section, and the second voltage curve has a sixth voltage curve section, wherein the processor is configured to extract a fifth feature on the basis of the fifth voltage curve section of the first voltage curve and a sixth feature on the basis of the sixth voltage curve section of the second voltage curve.

14. The battery management system according to claim 13, wherein the fifth feature corresponds to a capacity of the first battery cell and the sixth feature corresponds to a further capacity of the second battery cell.

15. The battery management system according to claim 1, wherein:
the interface is configured to:
obtain a number of groups to be generated, a further first multitude of voltage curves, and a further second multitude of voltage curves,
each of the further first multitude of voltage curves corresponds to a first battery cell of one of a further multitude of battery modules, and
each of the further second multitude of voltage curves corresponds to a second batter cell of a further multitude of battery modules, and
the processor is configured to assign each battery module of the further multitude of battery modules based on a classification algorithm to a multitude of groups, wherein a quantity of the multitude of groups is equal to the number of groups to be generated.

16. A method for battery management, the method comprising of the following steps:
obtaining a first voltage curve over a first battery cell of a battery module and a second voltage curve over a second battery cell of the battery module, wherein the first voltage curve has a first voltage curve section and a second voltage curve section, and wherein the second voltage curve has a third voltage curve section and a fourth voltage curve section;
determining a reference voltage curve on the basis of a mean voltage value from the first voltage curve and the second voltage curve, wherein the reference voltage curve has a first reference voltage curve section and a second reference voltage curve section;
comparing the first voltage curve to the reference voltage curve in order to obtain a first metric, which indicates a first voltage deviation between the first voltage curve section and the first reference voltage curve section and a second voltage deviation between the second voltage curve section and the second reference voltage curve section;
comparing the second voltage curve to the reference voltage curve in order to obtain a second metric, which indicates a third voltage deviation between the third voltage curve section and the first reference voltage curve section and a fourth voltage deviation between the fourth voltage curve section and the second reference voltage curve section; and
at least one of the following:
assigning a first electrical characteristic to the first voltage curve section and a second electrical characteristic to the second voltage curve section if the first metric is greater than the second metric in order to classify the battery module based on the first electrical characteristic and the second electrical characteristic; or
assigning a third electrical characteristic to the third voltage curve section and a fourth electrical characteristic to the fourth voltage curve section if the first metric is smaller than the second metric in order to classify the battery module based on the third electrical characteristic and the fourth electrical characteristic.
